(19) United States
(12) Patent Application Publication
(10) Pub. No.: US 2010/0206375 A1
(43) Pub. Date: Aug. 19, 2010

(54) THIN FILM SOLAR CELL HAVING OPAQUE AND HIGHLY REFLECTIVE PARTICLES AND MANUFACTURING METHOD THEREOF

(76) Inventors: Wei-Tse HSU, Houli Township (TW); Ping-Kuan Chang, Houli Township (TW); Kuang-Chieh Lai, Houli Township (TW)

Correspondence Address: SINORICA, LLC, 2275 Research Blvd., Suite 500, ROCKVILLE, MD, 20850, US

(21) Appl. No.: 12/704,129

(22) Filed: Feb. 11, 2010

(30) Foreign Application Priority Data
Feb. 13, 2009 (TW) 098104574

(51) Int. Cl. H01L 31/00

(52) U.S. Cl. 136/256

(57) ABSTRACT

A thin film solar cell having opaque and highly reflective particles and a manufacturing method thereof are provided. The thin film solar cell at least includes a substrate, a front electrode layer, a first photo-electric converting layer, a second photo-electric converting layer, and a back electrode layer. The particles are made of a highly conductive material, disposed between the first photo-electric converting layer and the second photo-electric converting layer, and distributed in a discontinuous manner. When an incident light strikes the surfaces of the particles, the incident light is reflected within the first photo-electric converting layer and the second photo-electric converting layer so as to increase the propagation path of the incident light through the first photo-electric converting layer and the second photo-electric converting layer.

### BACKGROUND OF THE INVENTION

1. Technical Field

The present invention relates to a thin film solar cell and a manufacturing method thereof. More particularly, the present invention relates to a thin film solar cell having opaque and highly reflective particles interposed between a first photo-electric converting layer and a second photo-electric converting layer, and a method for manufacturing the same.

2. Description of Related Art

According to current thin film solar cell technology, the efficiency of photoelectric conversion has its limit due to the recombination of electrons and holes in thin film solar cells and the loss of light. In order to increase photoelectric conversion efficiency, it is common practice to add an interlayer between a wide-band-gap material and a narrow-band-gap material of a thin film solar cell during the manufacturing process. Thus, when an incident light enters a thin film solar cell having such an interlayer, the narrow-band-gap material absorbs a part of the short-wavelength portion of the incident light, while the remaining part of the short-wavelength portion that is not absorbed strikes the interlayer and is reflected thereby. As a result, the reflected short-wavelength portion of the incident light has another chance to be absorbed, thereby increasing the power generation efficiency of the thin film solar cell. For example, U.S. Pat. No. 5,021,100 discloses a thin film solar cell having a dielectric selective reflection film that serves as the interlayer. Since the interlayer is intended to connect materials having band gaps of different ranges, it must have a certain degree of electric conductivity. Consequently, a leak current is very likely to occur during an external insulation step of the manufacturing process, and transmission of the leak current tends to cause short circuit.

To solve the short-circuit problem, referring to FIG. 1A, U.S. Pat. No. 6,632,993 provides a photovoltaic module in which an interlayer 5 is laser-scribed to form a separation groove 51 for interrupting current in the interlayer 5 and thereby preventing short circuit which may otherwise result from current flowing through the interlayer 5. U.S. Pat. No. 6,870,088 teaches a similar approach as shown in FIG. 1B of the present application. According to U.S. Pat. No. 6,870,088, a separation groove 8 is formed by a laser-scribing process after an interlayer 1 is deposited. Then, a second groove 9 extending through a first photo-electric converting layer 2 and a second photo-electric converting layer 3 is formed by a standard cutting process so as to prevent the aforesaid short-circuit problem. It should be particularly noted the second groove 9 is located within the separation groove 8. Both U.S. Pat. Nos. 6,632,993 and 6,870,088 prevent short circuit by forming a separation groove 51 or 8 through a laser-scribing process, which nevertheless increases the complexity and costs of the manufacturing process and is therefore unfavorable to mass production manufacturers. Hence, it is an important subject in the solar cell industry to enhance the power generation efficiency of thin film solar cells and prevent short circuit associated with the interlayer while lowering production costs.

### BRIEF SUMMARY OF THE INVENTION

To overcome the foregoing shortcomings of the prior art, the present invention provides a thin film solar cell having opaque and highly reflective particles and a method for manufacturing the same. The thin film solar cell at least includes a substrate, a front electrode layer, a first photo-electric converting layer, a second photo-electric converting layer, and a back electrode layer. The particles are interposed between the first photo-electric converting layer and the second photo-electric converting layer, and distributed in a discontinuous fashion. When an incident light strikes the surfaces of the opaque and highly reflective particles, the incident light is reflected within the first photo-electric converting layer and the second photo-electric converting layer, thus increasing the propagation path of the incident light through the first photo-electric converting layer and the second photo-electric converting layer.

Therefore, it is the primary objective of the present invention to provide a thin film solar cell having opaque and highly reflective particles, wherein the particles are interposed between a first photo-electric converting layer and a second photo-electric converting layer and distributed in a discontinuous manner. An incident light which strikes the surfaces of these opaque and highly reflective particles is reflected within the first photo-electric converting layer and the second photo-electric converting layer, such that the propagation direction of the long-wavelength portion (e g , infrared radiation) of the incident light that enters the second photo-electric converting layer is significantly altered. Thus, the propagation path of the incident light through the second photo-electric converting layer is increased to enhance the utilization rate of the long-wavelength portion (e.g., infrared radiation) of the incident light in the second photo-electric converting layer.

The secondary objective of the present invention is to provide a thin film solar cell having opaque and highly reflective particles, wherein the particles are interposed between a first photo-electric converting layer and a second photo-electric converting layer and distributed discontinuously. An incident light which strikes the surfaces of these opaque and highly reflective particles is reflected within the first photo-electric converting layer and the second photo-electric converting layer, such that a part of the short-wavelength portion of the incident light that is in the first photo-electric converting layer is reflected again, thereby increasing the propagation path of the incident light through the first photo-electric converting layer and allowing the reflected part of the short-wavelength portion of the incident light to be absorbed by the first photo-electric converting layer.

It is another objective of the present invention to provide a thin film solar cell having opaque and highly reflective particles, wherein the particles are interposed between a first photo-electric converting layer and a second photo-electric converting layer and have such small volumes that minimize the occurrence of short circuit caused by current conduction to these opaque and highly reflective particles when current flows from a back electrode layer or a front electrode layer through a second groove to the front electrode layer or the back electrode layer.

It is another objective of the present invention to provide a thin film solar cell having opaque and highly reflective particles, wherein the particles are interposed between a first photo-electric converting layer and a second photo-electric converting layer and are not limited in shape. For example, the opaque and highly reflective particles may each have a spherical, cubic, polygonal, or irregular shape. Preferably, the particles are spherical so as to allow reflection in arbitrary directions and angles and thereby increase the propagation path of an incident light.

It is a further objective of the present invention to provide a method for manufacturing a thin film solar cell having opaque and highly reflective particles, wherein the particles are interposed between a first photo-electric converting layer and a second photo-electric converting layer of the thin film solar cell and distributed in a discontinuous fashion. When an incident light strikes the surfaces of these opaque and highly reflective particles, it is reflected within the first photo-electric converting layer and the second photo-electric converting layer, thereby substantially changing the propagation direction of the long-wavelength portion (e g , infrared radiation) of the incident light that enters the second photo-electric converting layer, increasing the propagation path of the incident light through the second photo-electric converting layer, and consequently enhancing the utilization rate of the long-wavelength portion (e.g., infrared radiation) of the incident light in the second photo-electric converting layer.

It is a further objective of the present invention to provide a method for manufacturing a thin film solar cell having opaque and highly reflective particles, wherein the particles are interposed between a first photo-electric converting layer and a second photo-electric converting layer of the thin film solar cell and distributed in a discontinuous fashion. When an incident light strikes the surfaces of these opaque and highly reflective particles, it is reflected within the first photo-electric converting layer and the second photo-electric converting layer. As a result, a part of the short-wavelength portion of the incident light that is in the first photo-electric converting layer is reflected again, thereby increasing the propagation path of the incident light through the first photo-electric converting layer and allowing the reflected part of the short-wavelength portion of the incident light to be absorbed by the first photo-electric converting layer.

It is a further objective of the present invention to provide a method for manufacturing a thin film solar cell having opaque and highly reflective particles, wherein the particles are interposed between a first photo-electric converting layer and a second photo-electric converting layer of the thin film solar cell and have such small volumes that minimize the occurrence of short circuit caused by current conduction to these opaque and highly reflective particles when current flows from a back electrode layer or a front electrode layer through a second groove to the front electrode layer or the back electrode layer.

It is a further objective of the present invention to provide a method for manufacturing a thin film solar cell having opaque and highly reflective particles, wherein the particles are interposed between a first photo-electric converting layer and a second photo-electric converting layer of the thin film solar cell. The particles are not limited in shape and may each have a spherical, cubic, polygonal, or irregular shape. Preferably, the particles are spherical so as to allow reflection in arbitrary directions and angles and thereby increase the propagation path of an incident light.

### BRIEF DESCRIPTION OF THE SEVERAL VIEWS OF THE DRAWINGS

The invention as well as a preferred mode of use, further objectives, and advantages thereof will be best understood by referring to the following detailed description of illustrative embodiments in conjunction with the accompanying drawings, in which:

FIG. 1A is a sectional view of a thin film solar cell in the prior art;

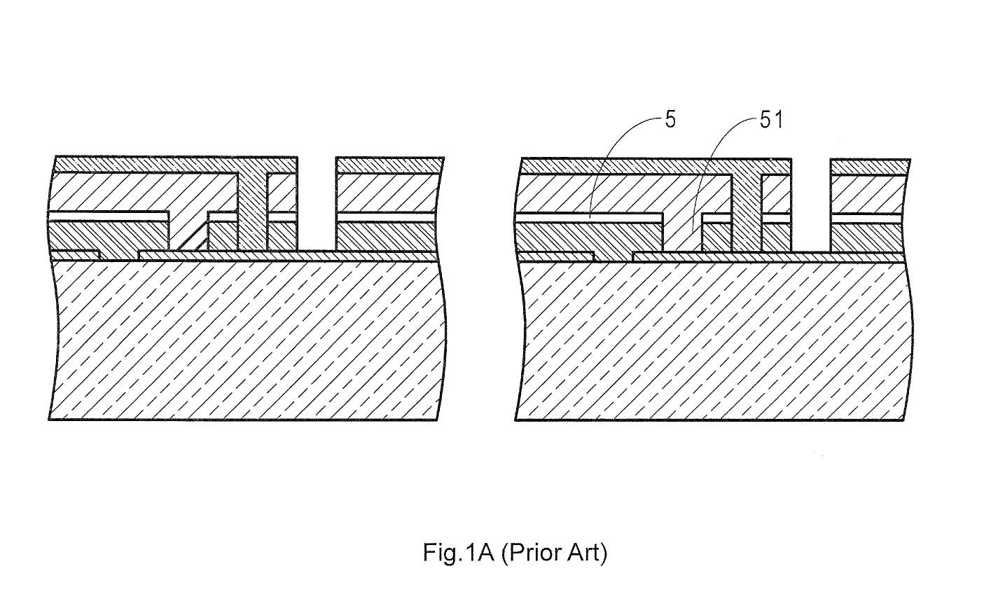

FIG. 1B is a sectional view of another thin film solar cell in the prior art;

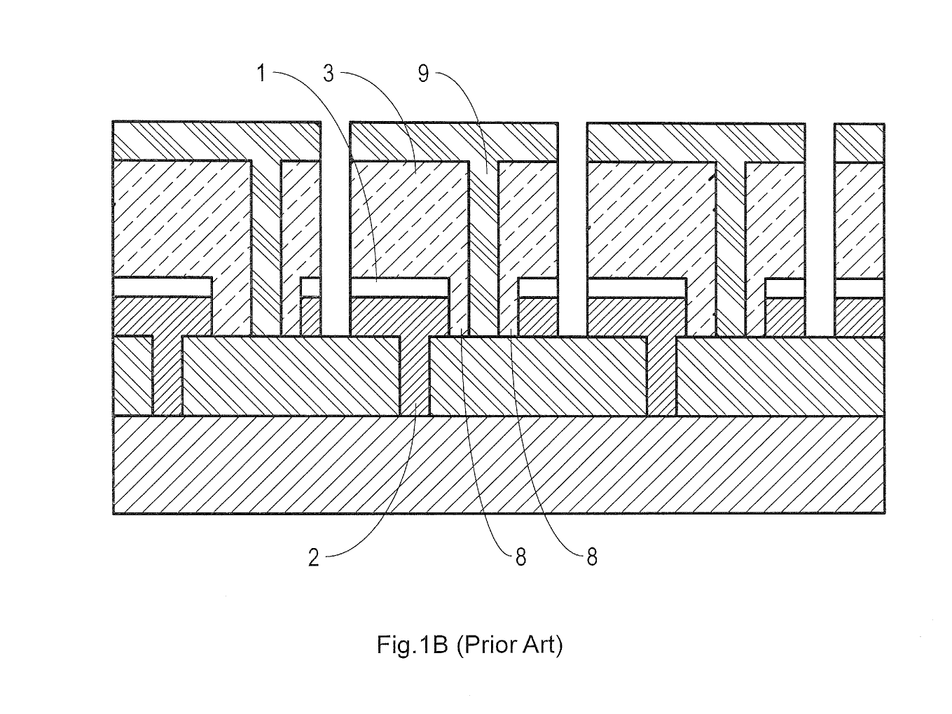

FIG. 2A is a sectional view of a thin film solar cell having opaque and highly reflective particles according to a first preferred embodiment of the present invention;

FIG. 2B is a partial perspective view of the thin film solar cell having the opaque and highly reflective particles according to the first preferred embodiment of the present invention, showing propagation paths of light reflected within a first photo-electric converting layer and a second photo-electric converting layer;

FIG. 2C is a sectional view showing current paths in the thin film solar cell having the opaque and highly reflective particles according to the first preferred embodiment of the present invention;

FIG. 3 is a sectional view of a thin film solar cell having opaque and highly reflective particles according to a second preferred embodiment of the present invention;

FIG. 4 is a flowchart of a method for manufacturing a thin film solar cell having opaque and highly reflective particles according to a third preferred embodiment of the present invention; and

FIG. 5 is a flowchart of a method for manufacturing a thin film solar cell having opaque and highly reflective particles according to a fourth preferred embodiment of the present invention.

### DETAILED DESCRIPTION OF THE INVENTION

The present invention relates to a thin film solar cell having opaque and highly reflective particles and a method for manufacturing the same. As the principles of photoelectric conversion as well as the design principles of solar cells are well known to a person of ordinary skill in the art, a detailed description of such principles is omitted herein. Besides, it is to be understood that the drawings referred to in the following description are intended to demonstrate features of the present invention only schematically, so the drawings are not necessarily drawn to scale.

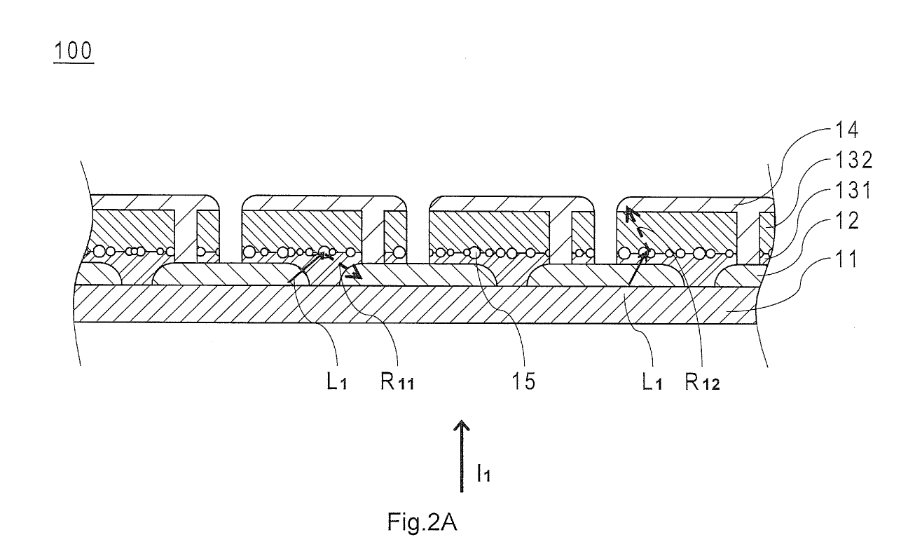

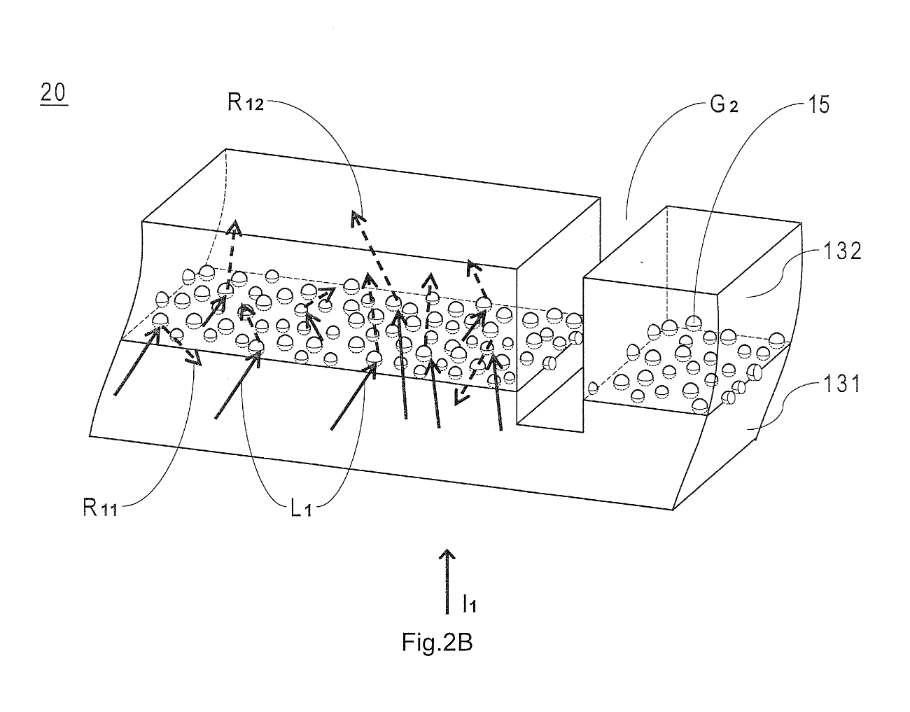

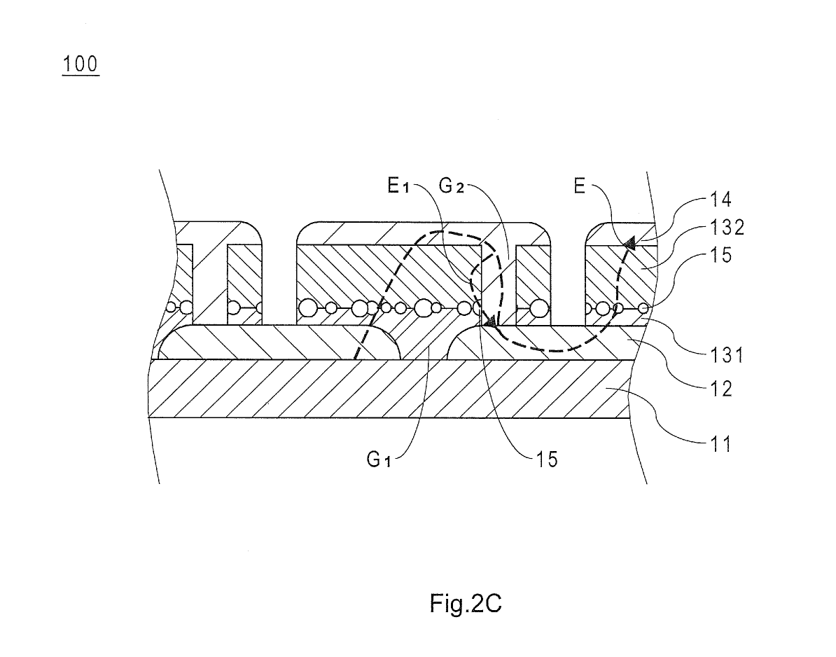

Referring to FIG. 2A for a thin film solar cell 100 having opaque and highly reflective particles according to a first preferred embodiment of the present invention, the thin film solar cell 100 at least includes a substrate 11, a front electrode layer 12, a first photo-electric converting layer 131, a second photo-electric converting layer 132, and a back electrode layer 14 stacked up in that order. A plurality of opaque and highly reflective particles 15 are interposed between the first photo-electric converting layer 131 and the second photo-electric converting layer 132 and distributed in a discontinuous manner. The opaque and highly reflective particles 15 are made of a material having high electric conductivity, preferably a metal such as silver, aluminum, indium or chromium. Referring to FIG. 2B, when an incident light L1 enters the thin film solar cell 100 from the substrate 11 along an entry direction I1 and strikes the surfaces of the highly reflective particles 15, the discontinuous distribution of the highly reflective particles 15 allows the incident light L1 to be reflected within the first photo-electric converting layer 131 and the second photo-electric converting layer 132, thus generating reflections R11 and R12 and increasing the propagation path of the incident light L1 through the first photo-electric converting layer 131 and the second photo-electric converting layer 132. Formation of the aforesaid propagation path can be divided into the following two cases, as described hereinafter with reference to FIG. 2A.

Case 1: When the incident light L1 enters the thin film solar cell 100 from the substrate 11 along the entry direction I1 and passes through the first photo-electric converting layer 131, the first photo-electric converting layer 131 absorbs a part of the short-wavelength portion of the incident light L1 while the remaining part of the short-wavelength portion that is not absorbed by the first photo-electric converting layer 131 strikes and is reflected by the surfaces of the opaque and highly reflective particles 15, thus generating reflection R11. The propagation path of the reflection R11 increases the propagation path of the incident light L1 through the first photo-electric converting layer 131 and allows the reflected part of the short-wavelength portion of the incident light L1 to be absorbed by the first photo-electric converting layer 131, thus enhancing the light absorption rate of the first photo-electric converting layer 131.

Case 2: When the incident light L1 enters the thin film solar cell 100 from the substrate 11 along the entry direction I1, passes through the first photo-electric converting layer 131, and strikes the surfaces of the opaque and highly reflective particles 15 tangentially, the incident light L1 is reflected toward the second photo-electric converting layer 132 and thus generates reflection R12. The propagation path of the reflection R12 lengthens the propagation path of the incident light L1 through the second photo-electric converting layer 132, thus increasing the reflectivity of the second photo-electric converting layer 132 to the long-wavelength portion (e.g., infrared radiation) of the incident light L1, as well as raising the utilization rate of the long-wavelength portion (e.g., infrared radiation) of the incident light L1 in the second photo-electric converting layer 132. If existing technology were used, which is poor at altering the propagation path of long-wavelength radiation, the second photo-electric converting layer 132 would be incapable of using and absorbing long-wavelength radiation (e.g., infrared radiation) effectively. In the present invention, however, the opaque and highly reflective particles 15 are conductors with high reflectivity and therefore contribute favorably to increasing the propagation path of infrared radiation and raising the utilization rate of infrared radiation in the second photo-electric converting layer 132.

Preferably, each opaque and highly reflective particle 15 has a particle size smaller than 300 nm. Moreover, the particles 15 may have equal or unequal particle sizes. What is important is that the opaque and highly reflective particles 15 should be distributed in a discontinuous fashion so that the incident light L1 can easily strike the opaque and highly reflective particles 15, thereby promoting the reflections R11 and R12. The spacing between the particles 15 can be designed according to practical needs without limitation. For example, the particles 15 may be distributed at equal or unequal spacings. In addition, there is no limitation on the shape of each opaque and highly reflective particle 15. Each particle 15 may have any one of a spherical shape, a cubic shape, a polygonal shape, and an irregular shape, or a combination thereof. As shown in FIG. 2B, the particles 15 are preferably spherical so that the reflections R11 and R12 can be generated in arbitrary directions and angles, thereby increasing the propagation path of the incident light L1.

The first photo-electric converting layer 131 and the second photo-electric converting layer 132 each have a band gap ranging from 0.5 eV to 2 eV. However, it should be pointed out that the first photo-electric converting layer 131 and the second photo-electric converting layer 132 substantially form a homojunction due to the opaque and highly reflective particles 15 between the first photo-electric converting layer 131 and the second photo-electric converting layer 132. Thus, band gap discontinuity typical of a heterojunction can be prevented.

Referring to FIG. 2C, a standard current path in the thin film solar cell 100 is indicated at E. The present invention can minimize the occurrence of short circuit caused by current conduction to the opaque and highly reflective particles 15 when current flows from the back electrode layer 14 through a second groove G2 to the front electrode layer 12, as shown by the current path E1. This is because even if the current E1 occurs, which contacts with the opaque and highly reflective particles 15 during its course from the back electrode layer 14 to the front electrode layer 12, the small volumes of the opaque and highly reflective particles 15, or of the even tinier particles cut out of the particles 15 when the second groove G2 is formed, allow the current E1 to continue flowing to the front electrode layer 12 without causing short circuit.

Generally, the substrate 11 is made of a transparent material. The front electrode layer 12 is a single-layer or multi-layer transparent conductive oxide (TCO) selected from tin dioxide (SnO₂), indium tin oxide (ITO), zinc oxide (ZnO), aluminum-doped zinc oxide (AZO), gallium-doped zinc oxide (GZO), and indium zinc oxide (IZO). Each of the first photo-electric converting layer 131 and the second photo-electric converting layer 132 has a single-layer or multi-layer structure and is made of a crystalline silicon semiconductor, an amorphous silicon semiconductor, a semiconductor compound, an organic semiconductor, or a sensitized dye. The back electrode layer 14 has a single-layer or multi-layer structure and includes a metal layer made of silver (Ag), aluminum (Al), chromium (Cr), titanium (Ti), nickel (Ni), or gold (Au). The back electrode layer 14 further includes a transparent conductive oxide selected from tin dioxide (SnO₂), indium tin oxide (ITO), zinc oxide (ZnO), aluminum-doped zinc oxide (AZO), gallium-doped zinc oxide (GZO), and indium zinc oxide (IZO).

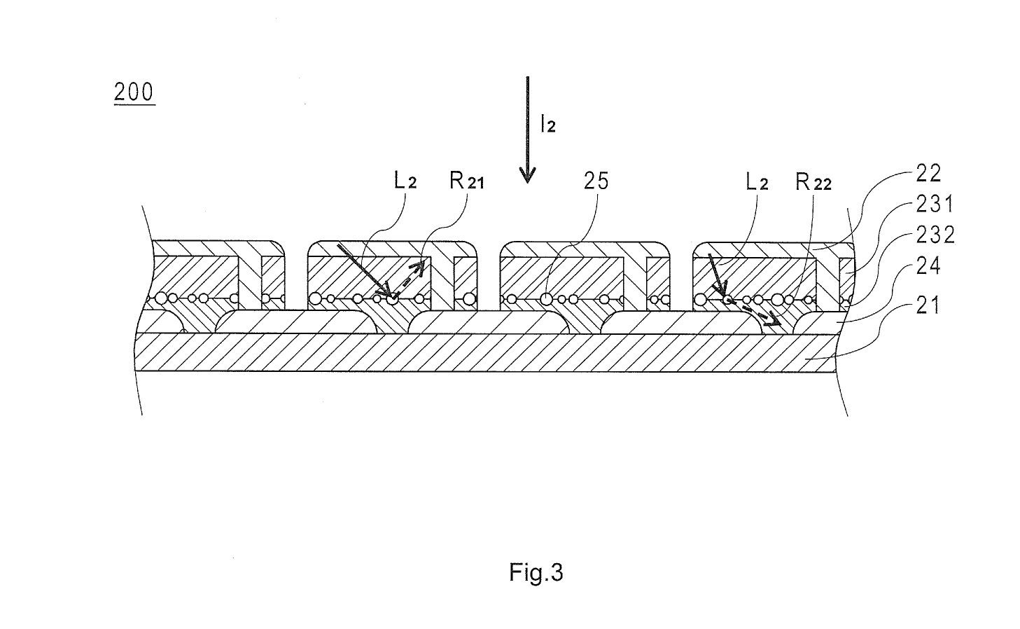

Referring to FIG. 3 for a thin film solar cell 200 having opaque and highly reflective particles according to a second preferred embodiment of the present invention, the thin film solar cell 200 at least includes a substrate 21, a back electrode layer 24, a second photo-electric converting layer 232, a first photo-electric converting layer 231, and a front electrode layer 22 stacked up in that order. A plurality of opaque and highly reflective particles 25 are interposed between the second photo-electric converting layer 232 and the first photo-electric converting layer 231 and distributed in a discontinuous manner. The opaque and highly reflective particles 25 are made of a material having high electric conductivity, preferably a metal such as silver, aluminum, indium or chromium. As shown in FIG. 3, when an incident light L2 enters the thin film solar cell 200 from the front electrode layer 22 along an entry direction 12 and strikes the surfaces of the highly reflective particles 25, the discontinuous distribution of the highly reflective particles 25 allows the incident light L2 to be reflected within the first photo-electric converting layer 231 and the second photo-electric converting layer 232, thus generating reflections R21 and R22 and increasing the propagation path of the incident light L2 through the first photo-electric converting layer 231 and the second photo-electric converting layer 232. The present embodiment differs from the first preferred embodiment mainly in the stacking order. The stacking order of the thin film solar cell 100 in the first preferred embodiment is: the substrate 11, the front electrode layer 12, the first photo-electric converting layer 131, the second photo-electric converting layer 132, and the back electrode layer 14, whereas the stacking order of the thin film solar cell 200 in the second preferred embodiment is: the substrate 21, the back electrode layer 24, the second photo-electric converting layer 232, the first photo-electric converting layer 231, and the front electrode layer 22. The present embodiment can also minimize the occurrence of short circuit caused by current conduction from the front electrode layer 22 through a second groove G2 to the opaque and highly reflective particles 25. Other features of the thin film solar cell 200 having the opaque and highly reflective particles 25 are identical to those in the first preferred embodiment.

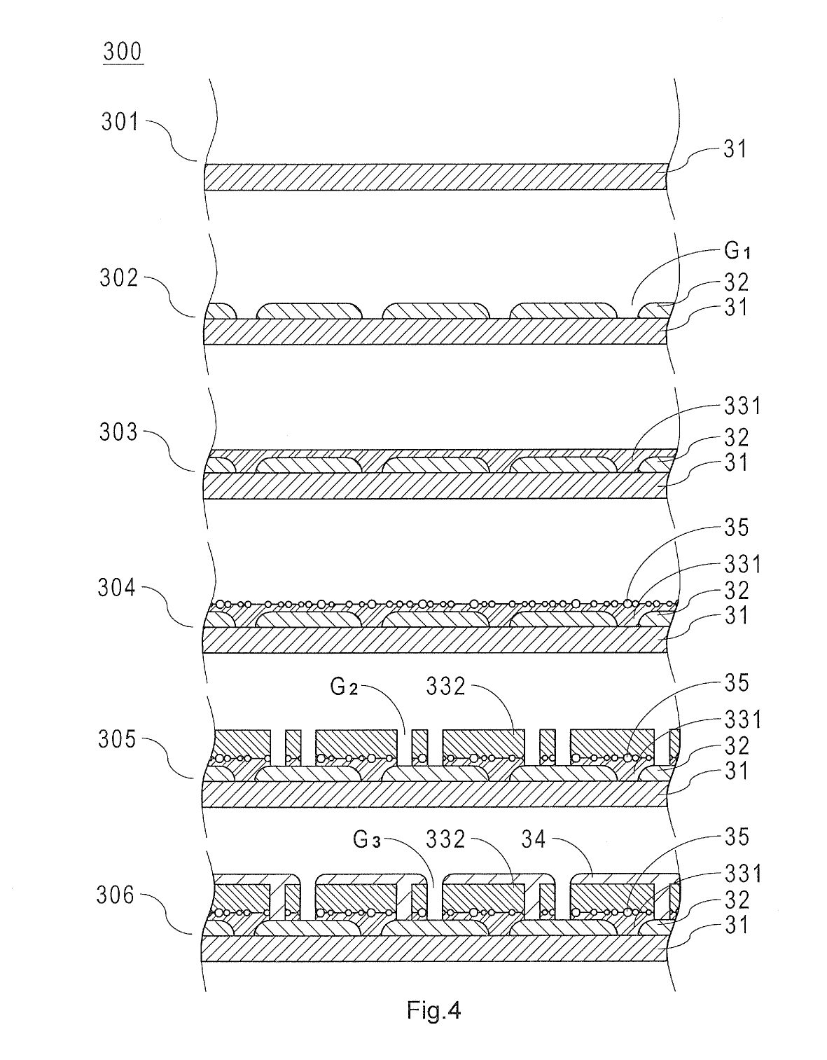

Please refer to FIG. 4 for a flowchart of a method for manufacturing a thin film solar cell 300 having opaque and highly reflective particles according to a third preferred embodiment of the present invention. The method includes:

(1) providing a substrate 31 (Step 301);

(2) forming a front electrode layer 32 on the substrate 31 (Step 302);

(3) forming a plurality of first grooves G1 in the front electrode layer 32 (Step 302);

(4) forming a first photo-electric converting layer 331 on the front electrode layer 32 (Step 303);

(5) forming a plurality of opaque, highly reflective, and discontinuously distributed particles 35 on the first photo-electric converting layer 331 by a physical plating process, such as vapor deposition or sputtering, wherein the particles 35 are made of a highly conductive material, preferably a metal such as silver or aluminum (Step 304);

(6) forming a second photo-electric converting layer 332 over the plurality of opaque and highly reflective particles 35 (Step 305);

(7) forming a plurality of second grooves G2 that extend from the second photo-electric converting layer 332 through the first photo-electric converting layer 331 (Step 305);

(8) forming a back electrode layer 34 on the second photo-electric converting layer 332 (Step 306); and

(9) forming a plurality of third grooves G3 that extend from the back electrode layer 34 through the first photo-electric converting layer 331 (Step 306).

The method of the present invention is characterized by the plurality of discrete, opaque, and highly reflective particles 35 formed of silver or aluminum by a physical plating process such as vapor deposition or sputtering. Hence, the method of the present invention dispenses with the laser-scribing process required in the prior art manufacturing method, thereby reducing production costs while still achieving the objective of minimizing the occurrence of short circuit. An even simpler way to provide the opaque and highly reflective particles 35 is to use commercially available nanoscale silver particles, which are silver particles having nanoscale dimensions and dispersed in a solution. These nanoscale silver particles can be spread over the first photo-electric converting layer 331 via a coating process, and after the solution is evaporated by heating, the opaque and highly reflective particles 35 are formed on the first photo-electric converting layer 331. Other features of the thin film solar cell 300 having the opaque and highly reflective particles 35 are identical to those in the first preferred embodiment.

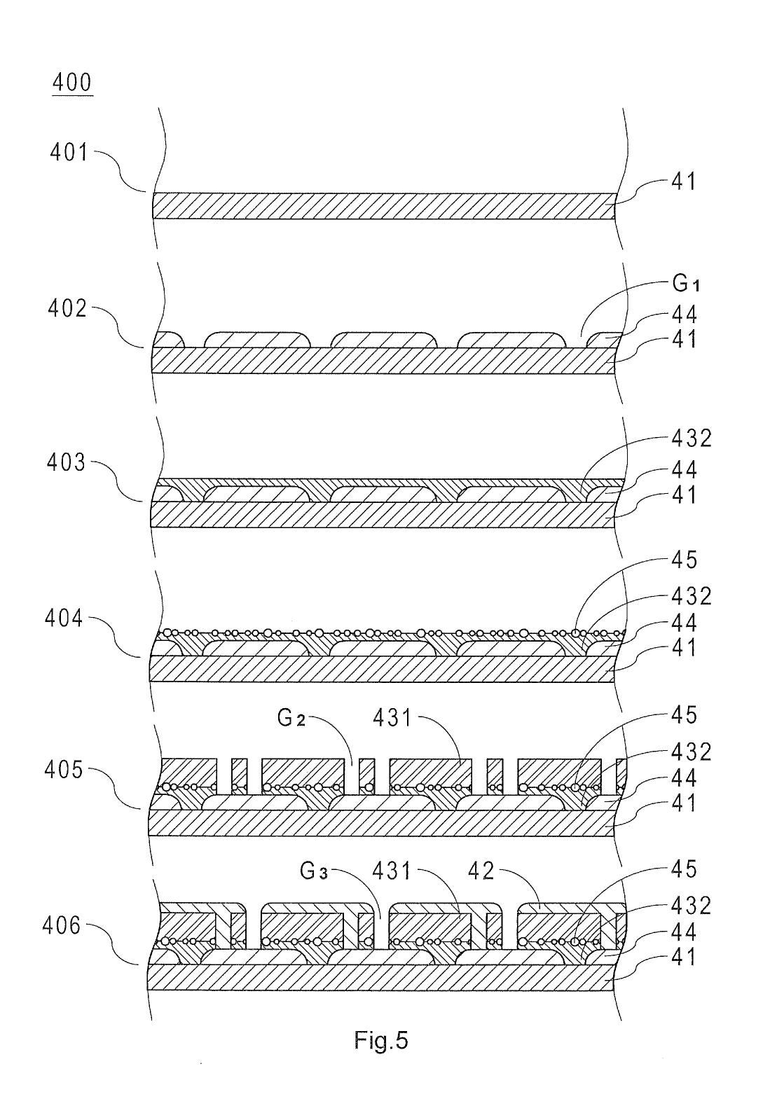

Please refer to FIG. 5 for a flowchart of a method for manufacturing a thin film solar cell 400 having opaque and highly reflective particles according to a fourth preferred embodiment of the present invention. The method includes:

(1) providing a substrate 41 (Step 401);

(2) forming a back electrode layer 44 on the substrate 41 (Step 402);

(3) forming a plurality of first grooves G1 in the back electrode layer 44 (Step 402);

(4) forming a second photo-electric converting layer 432 on the back electrode layer 44 (Step 403);

(5) forming a plurality of opaque, highly reflective, and discontinuously distributed particles 45 on the second photo-electric converting layer 432 by a physical plating process, such as vapor deposition or sputtering, wherein the particles 45 are made of a highly conductive material, preferably a metal such as silver or aluminum (Step 404);

(6) forming a first photo-electric converting layer 431 over the plurality of opaque and highly reflective particles 45 (Step 405);

(7) forming a plurality of second grooves G2 that extend from the first photo-electric converting layer 431 through the second photo-electric converting layer 432 (Step 405);

(8) forming a front electrode layer 42 on the first photo-electric converting layer 431 (Step 406); and

(9) forming a plurality of third grooves G3 that extend from the front electrode layer 42 through the second photo-electric converting layer 432 (Step 406).

The method of the present invention is characterized by the plurality of discrete, opaque, and highly reflective particles 45 formed of silver or aluminum by a physical plating process such as vapor deposition or sputtering. Hence, the method of the present invention spares the laser-scribing process required in the prior art manufacturing method, thereby reducing production costs while still achieving the objective of minimizing the occurrence of short circuit. An even simpler way to provide the opaque and highly reflective particles 45 is to use commercially available nanoscale silver particles, which are silver particles having nanoscale dimensions and dispersed in a solution. These nanoscale silver particles can be spread over the second photo-electric converting layer 432 via a coating process, and after the solution is evaporated by heating, the opaque and highly reflective particles 45 are formed on the second photo-electric converting layer 432. Other features of the thin film solar cell 400 having the opaque and highly reflective particles 45 are identical to those in the second preferred embodiment.

While the present invention has been described by reference to the preferred embodiments, it is understood that the embodiments are not intended to limit the scope of the present invention, which is defined only the appended claims. Moreover, as the contents disclosed herein should be readily understood and can be implemented by a person skilled in the art, all equivalent changes or modifications which do not depart from the spirit of the present invention should be encompassed by the claims.

What is claimed is:

1. A thin film solar cell having opaque and highly reflective particles, wherein the thin film solar cell at least comprises a substrate, a front electrode layer, a first photo-electric converting layer, a second photo-electric converting layer, and a back electrode layer stacked serially, the thin film solar cell being characterized in that:
a plurality of the opaque and highly reflective particles, which are made of a highly conductive material, are interposed between the first photo-electric converting layer and the second photo-electric converting layer and distributed in a discontinuous manner, wherein an incident light is reflected within the first photo-electric converting layer and the second photo-electric converting layer upon striking a surface of the opaque and highly reflective particles, thereby increasing the propagation path of the incident light through the first photo-electric converting layer and the second photo-electric converting layer.

2. The thin film solar cell of claim 1, wherein the opaque and highly reflective particles are made of a material selected from the group consisting of silver, aluminum, indium and chromium.

3. The thin film solar cell of claim 1, wherein the opaque and highly reflective particles have particle sizes smaller than 300 nm.

4. The thin film solar cell of claim 1, wherein the opaque and highly reflective particles have substantially identical particle sizes.

5. The thin film solar cell of claim 1, wherein the opaque and highly reflective particles have unequal particle sizes.

6. The thin film solar cell of claim 1, wherein the opaque and highly reflective particles are distributed at equal spacings.

7. The thin film solar cell of claim 1, wherein the opaque and highly reflective particles are distributed at unequal spacings.

8. The thin-film solar cell of claim 1, wherein the opaque and highly reflective particles each have a shape selected from the group consisting of a spherical shape, a cubic shape, a polygonal shape, and an irregular shape.

9. The thin film solar cell of claim 1, wherein the opaque and highly reflective particles are different in shape.

10. The thin film solar cell of claim 1, wherein both of the first photo-electric converting layer and the second photo-electric converting layer have a band gap ranging from 0.5 eV to 2 eV.

11. A thin film solar cell having opaque and highly reflective particles, wherein the thin film solar cell at least comprises a substrate, a back electrode layer, a second photo-electric converting layer, a first photo-electric converting layer, and a front electrode layer stacked serially, the thin film solar cell being characterized in that:
a plurality of the opaque and highly reflective particles, which are made of a highly conductive material, are interposed between the second photo-electric converting layer and the first photo-electric converting layer and distributed in a discontinuous manner, wherein an incident light is reflected within the first photo-electric converting layer and the second photo-electric converting layer upon striking a surface of the opaque and highly reflective particles, thereby increasing the propagation path of the incident light through the first photo-electric converting layer and the second photo-electric converting layer.

12. The thin film solar cell of claim 11, wherein the opaque and highly reflective particles are made of a material selected from the group consisting of silver, aluminum, indium and chromium.

13. The thin film solar cell of claim 11, wherein the opaque and highly reflective particles have particle sizes smaller than 300 nm.

14. The thin film solar cell of claim 11, wherein the opaque and highly reflective particles have substantially identical particle sizes.

15. The thin film solar cell of claim 11, wherein the opaque and highly reflective particles have unequal particle sizes.

16. The thin film solar cell of claim 11, wherein the opaque and highly reflective particles are distributed at equal spacings.

17. The thin film solar cell of claim 11, wherein the opaque and highly reflective particles are distributed at unequal spacings.

18. The thin-film solar cell of claim 11, wherein the opaque and highly reflective particles each have a shape selected from the group consisting of a spherical shape, a cubic shape, a polygonal shape, and an irregular shape.

19. The thin film solar cell of claim 11, wherein the opaque and highly reflective particles are different in shape.

20. The thin film solar cell of claim 11, wherein both of the first photo-electric converting layer and the second photo-electric converting layer have a band gap ranging from 0.5 eV to 2 eV.
